(19) United States
(12) Patent Application Publication
(10) Pub. No.: US 2011/0277823 A1
(43) Pub. Date: Nov. 17, 2011

(54) System and Method for High Yield Deposition of Conductive Materials onto Solar Cells

(75) Inventors: Qi Hua Fan, Ann Arbor, MI (US); Michael Deng, Sylvania, OH (US); Xianbo Liao, Toledo, OH (US); Xunming Deng, Sylvania, OH (US)

(73) Assignees: MWOE SOLAR, INC., Toledo, OH (US); UNIVERSITY OF TOLEDO, Toledo, OH (US)

(21) Appl. No.: 12/993,350

(22) PCT Filed: May 19, 2009
(86) PCT No.: PCT/US09/44492

§ 371 Date: Apr. 18, 2011

Related U.S. Application Data
(60) Provisional application No. 61/054,356, filed on May 19, 2008.

(51) Int. Cl. H01L 31/02; H01L 31/18; B05C 19/04

(52) U.S. Cl. 136/252; 118/623; 438/88; 438/98; 438/57; 257/E31.126

(57) ABSTRACT

A system for reducing damage to solar cells during a process for depositing a conductive material on a solar cell is disclosed where an electrical bias or floating potential is applied to the solar cell; and/or an electrical bias is applied to an external electrode(s) so that charged particles of a certain type are redirected away from the solar cells, avoiding the creation of a sufficiently high reverse bias on the solar cell to breakdown the cell.

### CROSS-REFERENCE TO RELATED APPLICATIONS

The present invention claims the benefit of the PCT/US2009/0444492 filed May 19. 2009, which claims priority to the provisional patent application Ser. No. 61/054,356 filed May 19, 2008.

### STATEMENT REGARDING FEDERALLY SPONSORED RESEARCH

This invention was made with government support under Grant No. 586077 awarded by National Renewable Energy Laboratory (NREL). The government has certain rights in the invention.

### FIELD OF THE INVENTION

This invention is generally directed to solar cells (photovoltaic devices), and particularly to a sputtering process for depositing electrode thin film(s) onto the solar cells to avoid damaging the devices and consequently to obtain high yield.

### BACKGROUND OF THE INVENTION

Solar cells usually have one or more semiconductor p-n junctions or p-i-n junctions. To collect light generated electrical charges, conductive electrode materials are deposited on both sides of the solar cells to form functional photovoltaic devices. Depending on the semiconductor material and its form, solar cells can be classified into several types, such as crystalline Si solar cells, thin film amorphous/microcrystalline Si and/or SiGe alloy based solar cells, CdTe solar cells, CuInGaSn solar cells, GaAs solar cells, and the like.

Each type of solar cell has specific features and has different methods of manufacture. For example, a substrate-type thin film amorphous/microcrystalline Si-based solar cell may be fabricated by passing a stainless steel web through a succession of chambers, each depositing one kind of thin film semiconductor layer; i.e., n-type, intrinsic (i-layer), and p-type Si, to form a thin film n-i-p semiconductor junction, or “stack.” Such a type of thin film semiconductor deposition process offers several distinct advantages over crystalline materials, insofar as they can be easily and economically fabricated into a variety of devices by mass production. In such cases, a substrate (such as a stainless steel substrate) serves as a back electrode (opaque), while a transparent conductive thin film, such as indium tin oxide (ITO), serves as a front electrode which allows light to pass therethrough.

The semiconductor layers forming the stack of the thin film amorphous/microcrystalline Si-based solar cells are usually deposited onto the substrate by a plasma enhanced chemical vapor deposition (PECVD), while the electrode thin films are deposited onto the stack by a physical vapor deposition (PVD)—most commonly by sputtering.

It has been noted, however, that the type of sputtering process used for depositing the transparent conductive thin film onto the solar cell stack has a significant effect on the yield of the device. This effect is more pronounced for amorphous/microcrystalline Si-based thin film solar cells grown on metal substrate. Among various types of sputtering processes, a radio frequency (RF) sputtering process shows less impact on the yield of the solar cell, while a direct current (DC) sputtering process usually causes serious damage to the solar cell stack, as evidenced by zero open circuit voltage at room temperature. Therefore, the RF sputtering process is commonly used to deposit the electrode thin film.

However, even for the RF sputtering deposition process, the yield of the solar cell is still not satisfactory. The yield of the solar cell with an RF-sputtered electrode film is dependent on a number of factors such as the substrate surface roughness, the sputtering system configuration, the sputtering parameters, and deposition process of the p-layer or the n-layer (whichever is in contact with the top electrode film).

In the past, the difficulty in optimizing these factors had lead to poor repeatability and made quality control difficult in large area mass production. Furthermore, the RF sputtering process requires a complicated and expensive power system and matching network, while the ultimate rate of deposition is low; generally, about half the rate as that of a DC sputtering deposition process. As a consequence, this increases the manufacturing costs for producing photovoltaic devices, such as solar panels and the like.

What is needed is a method for efficiently producing photovoltaic devices and solar cells which reduces or eliminates damage to the solar cell during a sputtering deposition process where a conductive material is applied to the solar cell.

There is a further need for a system which achieves a sufficiently high deposition rate so as to make the manufacturing process rapid, energy conservative, and economically feasible.

### SUMMARY OF THE INVENTION

In a first broad aspect, there is provided herein a method for depositing a conductive material on a solar cell having a doped outer layer, the method comprising:

applying an electrical bias to the solar cell, grounding the solar cell, or setting the solar cell at an electrically floating potential;

generating a plasma of negatively and positively charged particles to produce a sputtering of a target material; and,

depositing the target material as a thin film onto the doped outer layer of the solar cell;

where the applied electrical bias/grounding/floating potential to the solar cell reduces the amount of certain types of charged particles reaching the doped outer layer of the solar cell.

In certain embodiments, where the solar cell is deposited on a substrate, the method can include applying the electrical bias to the substrate, grounding the substrate, or setting the substrate at an electrically floating potential.

In certain embodiments, the electrical bias/grounding/floating potential is sufficient to substantially prevent certain of the charged particles from creating a sufficiently high reverse bias on the solar cell so as to damage the solar cell.

In certain embodiments, the target material comprises a transparent conductive electrode (TCE) material. In certain embodiments, the conductive material comprises one or more layers of transparent conductive oxide (TCO) film(s), one or more layers of metal film(s), or a combination of both.

In another aspect, there is provided herein a method for reducing damage to solar cells during a sputtering deposition process of a conductive material on a doped outer layer of the solar cell, the method comprising:

applying an electrical bias to the solar cell, grounding the solar cell, or setting the solar cell at an electrically floating potential;

generating a plasma of negatively and positively charged particles to produce a sputtering of a target material, and

depositing the target material onto the doped outer layer of the solar cell,

wherein the applied electrical bias/grounding/floating potential to the solar cell reduces the amount of certain types of charged particles reaching the doped outer layer of the solar cell.

In still another aspect, there is provided herein an apparatus for depositing a target material on a solar cell having a doped outer layer.

In another broad aspect, there is provided herein a method for depositing a conductive material on a solar cell having a doped outer layer, the method comprising:

applying an electrical bias to at least one external electrode positioned in a spaced relationship to the doped outer layer of the solar cell;

generating a plasma of negatively and positively charged particles to produce a sputtering of a target material, and

depositing the target material onto the doped outer layer of the solar cell, the electrical bias applied to the external electrode causing a certain type of charged particles in the plasma to move preferentially toward the external electrode(s), reducing the amount of such charged particles that reach the doped outer layer of the solar cell to create a reverse bias sufficiently high as to damage the solar cell during the deposition process.

The electrical bias applied to the external electrode(s) depends on the solar cell structure. In certain embodiments, where the solar cell has a p-type layer as the doped outer semiconductor layer, the method includes applying a positive bias to the external electrode(s) or setting the external electrode(s) at ground potential. In certain embodiments, where the solar cell has an n-type layer as the doped outer semiconductor layer, the method includes applying a negative bias to the external electrode(s) or setting the external electrode(s) at ground potential.

In certain embodiments, the method further includes applying an electrical bias to the solar cell along with applying an electrical bias of a different polarity to the external electrode(s).

In yet another aspect, there is provided herein a method for reducing damage to solar cells during a sputtering deposition process of a conductive material on a doped outer layer of the solar cell, the method comprising:

applying an electrical bias to at least one external electrode positioned in a spaced relationship to the doped outer layer of the solar cell;

generating a plasma of negatively and positively charged particles to produce a sputtering of a target material, and

depositing the target material onto the doped outer layer of the solar cell,

the applied electrical bias to the solar cell reducing the amount of certain types of charged particles reaching the doped outer layer of the solar cell.

In yet another broad aspect, there is provided herein a photovoltaic device made using any of the methods described herein.

In yet another broad aspect, there is provided herein a photovoltaic device made using any one of the apparatuses described herein.

Various objects and advantages of this invention will become apparent to those skilled in the art from the following detailed description of the preferred embodiment, when read in light of the accompanying drawings.

### BRIEF DESCRIPTION OF THE DRAWINGS

FIG. 1 is a schematic illustration of a first embodiment of a deposition system where the substrate, on which the solar cell is formed, can be set to different potentials (e.g., floating, negative, positive, or ground) during the deposition of a conductive electrode material onto a solar cell.

FIG. 2 is a schematic illustration of a second embodiment of a deposition system where one or more external electrodes are positioned in front of the solar cell.

FIG. 3 is a table showing the room temperature open circuit voltage (rV_{oc}) of various silicon-based thin film n-i-p solar cells grown on a stainless steel substrate with a top ITO film deposited by direct current (DC) sputtering.

FIG. 4 is a table showing the room temperature open circuit voltage (rV_{oc}) of various silicon-based thin film n-i-p solar cells grown on a stainless steel substrate with a top ITO film deposited by radio frequency (RF) sputtering.

FIG. 5 is a table showing the room temperature open circuit voltage (rV_{oc}) of 17 silicon-based thin film n-i-p solar cells grown on a stainless steel substrate with a top ITO film deposited by direct current (DC) sputtering at different DC powers. The substrate is set at a floating potential during the sputtering process.

FIG. 6A is a schematic illustration of a structure of a solar cell grown on a metal substrate during a DC sputtering deposition of a conductive electrode film where a grounded substrate or positively biased substrate results in an electrical field E pointing to the cathode.

FIG. 6B is a graph showing that the electrical field shown in the embodiment of FIG. 6A leads to a reverse bias of the n-i-p junction and may cause Zener or avalanche breakdown of the cell, as shown by the arrow in the solar cell I-V curve in FIG. 6B.

FIG. 7A is a schematic illustration of a structure of a solar cell grown on a metal substrate during a DC sputtering deposition of a conductive electrode film where the substrate is at a floating potential or a negatively biased, which, in a region near the anode, results in an electrical field E pointing to the substrate.

FIG. 7B is a graph showing that the electrical field shown in the embodiment of FIG. 7A leads to a forward bias to the n-i-p junction and will not damage the cell, as shown by the arrow in the solar cell I-V curve in FIG. 7B.

FIG. 8 is a schematic illustration of a structure of a solar cell grown on a metal substrate during an RF sputtering deposition of a conductive electrode film. The substrate is grounded.

FIG. 9 is a graph showing a reverse I-V curve of a solar cell with a top electrode film deposited by DC sputtering, during which the substrate is set at a floating potential.

### DETAILED DESCRIPTION OF THE PREFERRED EMBODIMENT(S)

In a first, broad aspect, there is described herein a system for reducing or substantially preventing damaging a solar cell during the sputtering deposition of a conductive electrode thin film material onto an outer layer of the solar cell.

It is to be understood that, as generally described herein, a thin film photovoltaic (PV) device generally comprises a substrate; (optionally, a back reflector that consists of a reflective metal layer and a transparent conductive oxide layer deposited on the substrate); a thin film silicon-based semiconductor body, or “solar cell”, deposited on the substrate; and a conductive electrode layer deposited on a top surface of the solar cell.

In a particular aspect, there is described herein a system for depositing a transparent conductive electrode (TCE) thin film on a top surface of a solar cell (i.e., semiconductor junction or “stack” as further described herein) that has been deposited on a substrate. The system includes controlling the electrical potential of the substrate during the deposition of the transparent conductive electrode (TCE) thin film such that charged particles of a certain type are not directed toward the solar cell and/or do not create a reverse bias that is sufficiently high to damage the solar cell.

Substrate

In certain embodiments, the substrate may be made of a single-substance conductive material. In other embodiments, the substrate can be formed as a conductive layer on a support where the support is composed of an insulating material or a conductive material.

The conductive materials may include, for example, metals such as NiCr, stainless steel, Al, Cr, Mo, Au, Nb, Ta, V, Ti, Pt, Pb, Sn, and alloys thereof.

In addition, the thickness of the substrate may be appropriately determined so as to be able to form photovoltaic elements as desired, but when the photovoltaic element is required to have flexibility, the substrate can be made as thin as possible within the range of sufficiently exhibiting the support function.

Doped Layers (p-Layer, n-Layer)

In general, the PV devices rely on the semiconductor body to convert sunlight into electricity. The semiconductor body is generally comprised of at least two layers of opposite types—one layer being an n-layer with an extra concentration of negatively charged electrons, and the other layer being a p-layer with an extra concentration of positively charged holes.

It is to be understood that, in certain embodiments, the solar cell stack can be comprised of a single- or multi-junction solar cell stack that includes at least one n-type layer and at least one p-type layer. In certain embodiments, the semiconductor junction (i.e., the “stack” comprised of n-p, n-i-p, p-i-n, etc. layers) can be deposited onto the substrate. Also, in certain embodiments, the solar cell stack can have a laminated pin structure such as: “pinpin” structures, “pinpinpin” structures, “nipnip” structures or “nipnipnip” structures.

It is to be understood that the method described herein can successfully be applied to single, double and triple junction solar cells (either of the “nip” type or “pin” type). For example, a photovoltaic device can include a layer of transparent, electrically-conductive electrode material, a solar cell material (i.e., “nip” or “pin” material), and a back electrode.

The solar cell layers, i.e., n-layer, i-layer, p-layer, can be made by at least one of the following methods: cathodic direct current glow discharge, anodic direct current glow discharge, radio frequency glow discharge, very high frequency (VHF) glow discharge, alternate current glow discharge, or microwave glow discharge at a pressure ranging from about 0.1 to about 10 TORR with a dilution ratio of dilutant to feedstock (deposition gas) ranging from about 5:1 to about 200:1.

In certain embodiments, n-type doping may be achieved with an n-type chemical dopant (“dopant”), such as, e.g., PH₃; p-type doping may be achieved using a p-type chemical dopant, such as, e.g., BF₃.

One non-limiting example of a solar cell is an amorphous silicon semiconductor solar cell which is comprised of a p-i-n amorphous silicon thin film semiconductor. The amorphous silicon semiconductor material can be comprised of one or more of: hydrogenated amorphous silicon, hydrogenated amorphous silicon carbon or hydrogenated amorphous silicon germanium. In certain other embodiments, the stack of the doped layer(s) can be composed of a non-single crystalline silicon type semiconductor. Examples of the “amorphous” (abbreviated as “a-”) silicon type semiconductor include a-Si, a-SiGe, a-SiC, a-SiO, a-SiN, a-SiCO, a-SiON, a-SiNC, a-SiGeC, a-SiGeN, a-SiGeO, a-SiCON, and a-SiGeCON.

i-Layer

In certain embodiments, the solar cell semiconductor junction, or stack, includes an intrinsic layer (i-layer) interposed between an n-layer and a p-layer. In one non-limiting example, an amorphous silicon-containing, undoped, active intrinsic i-layer can be deposited upon, positioned between, and connected to the p-layer and an n-type amorphous silicon-containing layer.

In certain embodiments, each photovoltaic junction also contains an intrinsic layer (i-layer) sandwiched between an n-layer and a p-layer. The i-layer can be an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these semiconductor materials. The semiconductor material generally has a bandgap energy (or bandgap), or multiple bandgaps that are appropriately selected to achieve output performance of the solar cell based on factors, such as, cell configuration and materials, efficiency, and available light energy. The bandgap may also be adjusted, for example, by varying the content of germanium or hydrogen in hydrogenated amorphous silicon germanium alloy (a-Si₁₋ₓGeₓ:H).

In certain embodiments, the i-layer may be made of an amorphous silicon type semiconductor, whether slightly p-type or slightly n-type. Other non-limiting examples of the amorphous silicon type semiconductors may include a-Si, a-SiC, a-SiO, a-SiN, a-SiCO, a-SiON, a-SiNC, a-SiCON, a-SiGe, a-SiGeC, a-SiGeO, a-SiGeN, a-SiCON, a-SiGeNC, and a-SiGeCON.

Transparent Conductive Electrode Layer (TCE)

Non-limiting examples of suitable transparent conductive electrode (TCE) materials include: indium oxide (In₂O₃), tin oxide (SnO₂), ITO (In₂O₃+SnO₂), to which fluorine, zinc oxide, silver, combinations of or alloys of these materials may be added.

The deposition of the transparent conductive electrode (TCE) is optimally performed by a suitable deposition method such as a direct current (DC) sputtering or radio frequency (RF) sputtering deposition process.

Reference will now be made to the figures, wherein like numerals refer to like parts throughout. It will be appreciated that the figures are not necessarily drawn to scale.

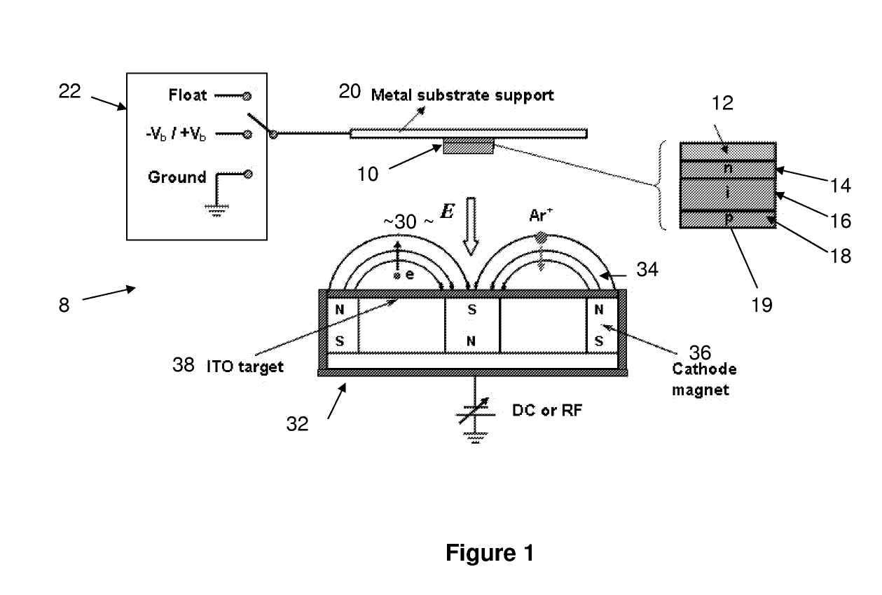

Referring now to the embodiment shown in FIG. 1, a system 8 for forming a photovoltaic device is schematically illustrated. A solar cell 10 is schematically illustrated as being deposited on a substrate 12. The solar cell 10 is schematically illustrated as having a doped n-layer 14, an i-layer 16 and a doped p-layer 18. The substrate 12 is in contact with a metal support 20. The metal support 20 is operatively connected to a device 22 configured for supplying an electrical bias to the metal substrate 12 (i.e., by passing electrical energy through the metal support 22). In other embodiments, the electrical bias may be applied directly to the substrate 12.

The p-type layer 18 is exposed to a plasma 30 comprised of positively and negatively charged particles. It is to be understood that, in certain embodiments, the plasma 30 can be generated using a magnetron cathode system 32 which can be operated by either a direct current (DC) power system or a radio frequency (RF) power system. In the schematic illustration of FIG. 1, the magnetron cathode system 32 includes one or more cathode magnets 36 that generate a proper magnetic flux 34 in front of the ITO target 38. It is to be further understood that the plasma 30 being generated will include both negatively charged particles, such as electrons (“e”), and positively charged particles, such as “Ar⁺”.

In the embodiment illustrated in FIG. 1, when the p-layer 18 is the outer layer, the method includes applying a negative bias to the substrate 12 and thus, to the solar cell 10. The negative bias redirects the negatively charged particles “e” in the plasma 30 away from the solar cell 10 during the deposition of a thin film of the transparent conductive electrode material onto an outer surface 19 of the p-layer 18. By substantially preventing the negatively charged particles from accumulating on the outer surface 19 of the p-layer 18, any damage to the solar cell 10 that would be caused by a reverse bias on the solar cell structure is minimized or avoided.

In the embodiment shown in FIG. 1, the deposition system 8 can be configured such that the substrate 12, on which the solar cell 10 is formed, can be set to a different potential (floating, negative, positive, or ground) during the deposition of the transparent conductive electrode (TCE) onto the silicon based thin film n-i-p solar cell 10. For example, in the FIG. 1 embodiment, the substrate 12 may be set at a floating potential or at a negative potential.

In another embodiment, the solar cell 10 can have an n-type layer, such as p-layer 14, facing the plasma where a positively biased substrate, similar to substrate 12, redirects positively charged particles away from the solar cell, avoiding potential damage on the solar cells caused by reverse bias on the solar cell structure.

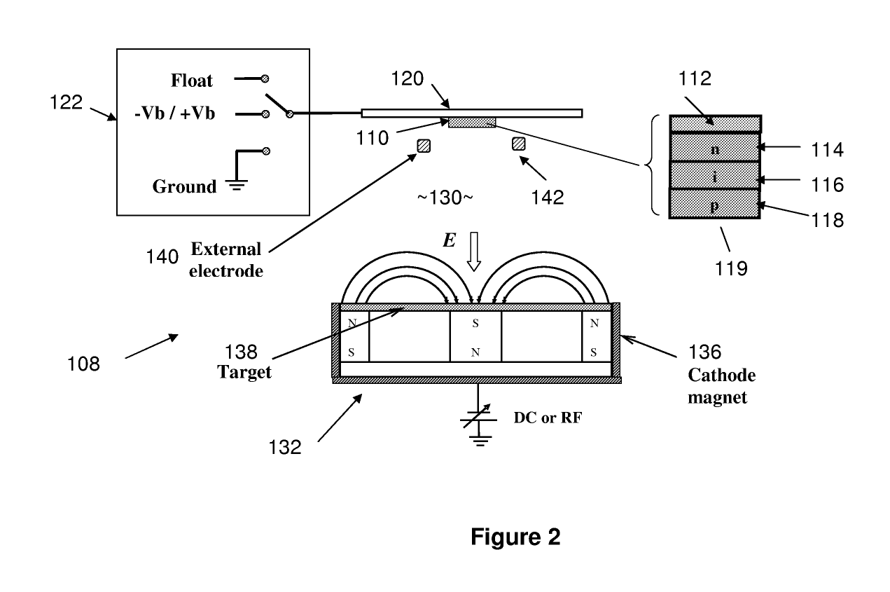

Referring now to the embodiment shown in FIG. 2, a system 108 for forming a photovoltaic device is schematically illustrated. A solar cell 110 is schematically illustrated as being deposited on a substrate 112. The solar cell 110 is shown having a doped n-layer 114, an i-layer 116 and a doped p-layer 118. The substrate 112 is in contact with a metal support 120. The metal support 120 is operatively connected to a device 122 configured for supplying an electrical bias to the metal substrate 112 (i.e., by passing electrical energy through the metal support 122). In certain embodiments, the electrical bias may be applied directly to the substrate 112.

The p-type layer 118 is exposed to a plasma 130 comprised of positively and negatively charged particles. It is to be understood that in certain embodiments, the plasma 130 can be generated using a magnetron cathode system 132 which can be operated by either a direct current (DC) power system or a radio frequency (RF) power system. In the schematic illustration of FIG. 2, the magnetron cathode system 132 includes one or more cathode magnets 136 and an ITO target 138. It is to be further understood that the plasma 130 being generated will include both negatively charged particles and positively charged particles.

The system 108 includes one or more external electrodes 140 and 142, being set in a spaced relationship from an outer surface 119 of the solar cell 110. During the deposition of the transparent conductive electrode film onto the solar cell 110, the external electrode(s) 140 and/or 142 can be set at a potential different from that of the support 120, depending on the solar cell structure.

The movement of the charged particles in the plasma can be controlled also by a bias applied on the external electrodes 140 and/or 142 located in front of the solar cell 110 during the sputtering deposition process. Movement of the charged particles is controlled because negatively charged particles prefer to move towards a higher potential, while positively charged particles tend to move towards a lower potential.

With a configuration shown in FIG. 2, a positive potential can be applied to the external electrode(s) 140 and/or 142 to attract negatively charged electrons so as to avoid forming a reverse bias on the solar cell 110 with an n-i-p structure. In another embodiment, a negative potential can be applied to the external electrode(s) 140 and/or 142 where the solar cell has a p-i-n structure.

Thus, the bias potential on the external electrode(s) 140 and/or 142 is applied in such a way to avoid negatively charged particles in the plasma from reaching solar cells 110 with p-layer facing the plasma 130, or to avoid positively charged particles from reaching solar cells with an n-layer facing the plasma 130.

Different combinations of bias potentials can be applied to the external electrode(s) 140, 142, and the substrate 112. For example, in an embodiment shown in FIG. 2 where a stainless steel material is used as the substrate 112 and a silicon-based thin film n-i-p solar cell 110 is formed on the stainless steel substrate 112. The substrate 112 can be grounded, while a positive bias is applied to the external electrode(s) 140 and/or 142 during the sputtering deposition of the front electrode film.

### EXAMPLES

The invention is further defined in the following Examples. It should be understood that these Examples, while indicating preferred embodiments of the invention, are given by way of illustration only. From the above discussion and these Examples, one skilled in the art can ascertain the essential characteristics of this invention, and without departing from the spirit and scope thereof, can make various changes and modifications of the invention to adapt it to various usages and conditions. All publications, including patents and non-patent literature, referred to in this specification are expressly incorporated by reference herein.

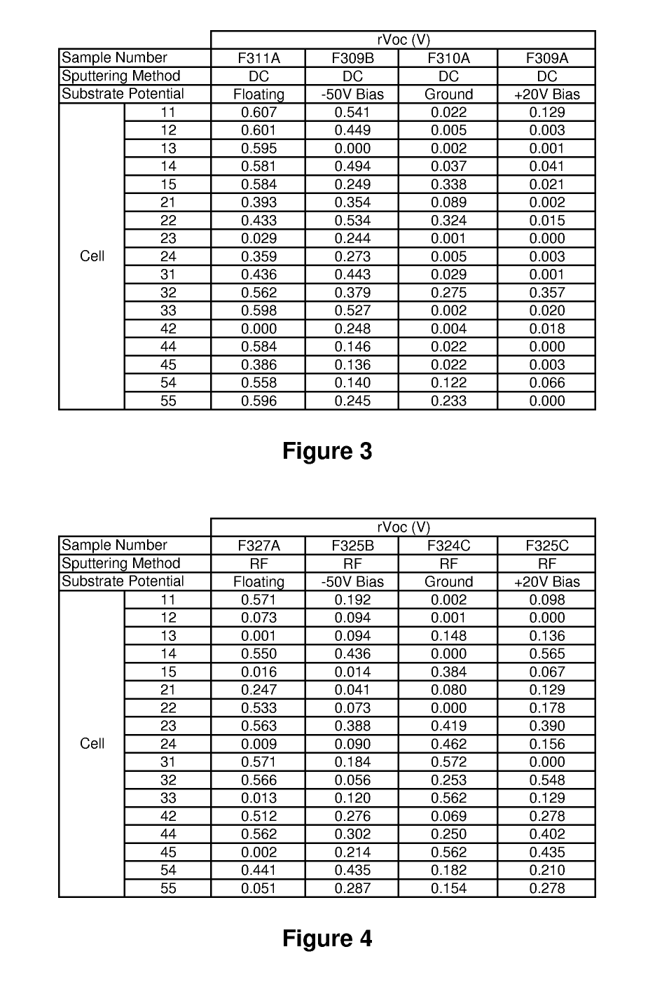

FIG. 3 is a table showing the room temperature open circuit voltage (rV_{oc}) of 17 silicon-based thin film n-i-p solar cells grown on a stainless steel substrate. The difference between the four samples (shown in four columns) is the sputtering process of the front electrode film, which is a transparent conductive electrode ITO film deposited by DC sputtering at a power of 150 W with different substrate potential. The solar cell is considered damaged or partly damaged if the rV_{oc} is smaller than 0.1 V, which is an indication of the yield of the solar cells. It can be seen that floating or negatively biasing the substrate generates a much higher yield than grounding or positively biasing the substrate.

FIG. 4 is a table showing the room temperature open circuit voltage (rV_{oc}) of 17 silicon based thin film n-i-p solar cells grown on stainless steel substrate. The difference between the four samples is the sputtering process of the front electrode film, which is a transparent conductive electrode ITO film deposited by RF sputtering at a power of 500 W with different substrate potentials. The RF power level is chosen in such a way that it provides a deposition rate similar to that of DC sputtering at 150 W. The cell is considered damaged or partly damaged if the rV_{oc} is smaller than 0.1 V, which is an indication of the yield of the solar cells.

Comparing the DC and RF sputtering processes (i.e., FIGS. 3 and 4) with the grounded substrate in both cases, the RF sputtering process produces much better yield and cell performance than the DC sputtering process. This is generally the reason why a RF sputtering process is most commonly used to deposit TCE films onto silicon-based thin film n-i-p solar cells that are grown on a metal substrate. However, once the substrate is set at a floating potential or negative bias potential, it can be seen that the DC sputtering process leads to an even higher yield and better performance than the RF sputtering process.

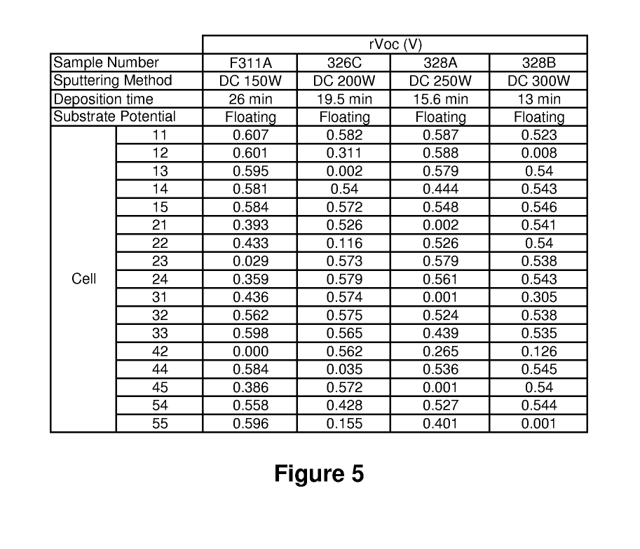

FIG. 5 is a table showing the room temperature open circuit voltage (rV_{oc}) of 17 silicon-based thin film n-i-p solar cells grown on a stainless steel substrate. The difference between the samples is the DC sputtering power employed for the deposition of a transparent conductive electrode (TCE) comprised of an ITO film and the time of deposition. The substrate is set at a floating potential during the sputtering process. It can be seen that, on average, the solar cell performance and yield are still quite good, even when the power level is doubled.

As such, using the methods described herein, a high rate deposition of the top transparent conductive electrode (TCE) film can be realized without compromising the solar cell performance.

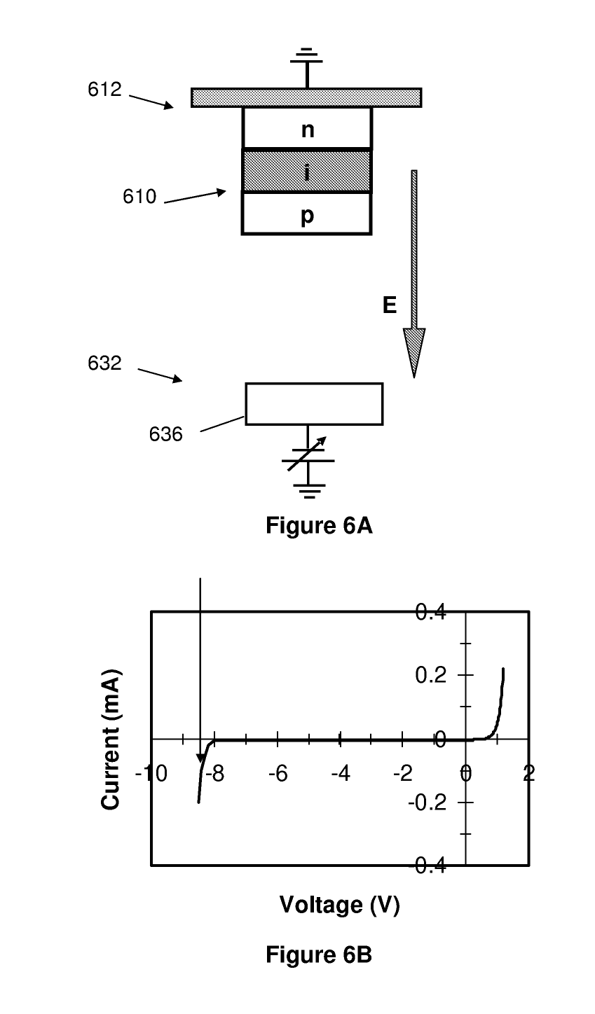

FIG. 6A is a schematic illustration of a solar cell 610 grown on a metal substrate 612. A DC sputtering deposition system 632 (having a cathode 636) is employed to deposit a transparent conductive electrode film onto the solar cell 610. If the substrate 612 is grounded or positively biased, an electrical field E pointing to the cathode 636 is formed between the substrate and the cathode. Such an electrical field leads to a reverse bias of the n-i-p junction and may cause Zener or avalanche breakdown of the cell, as shown by the arrow in the solar cell I-V curve in FIG. 6B.

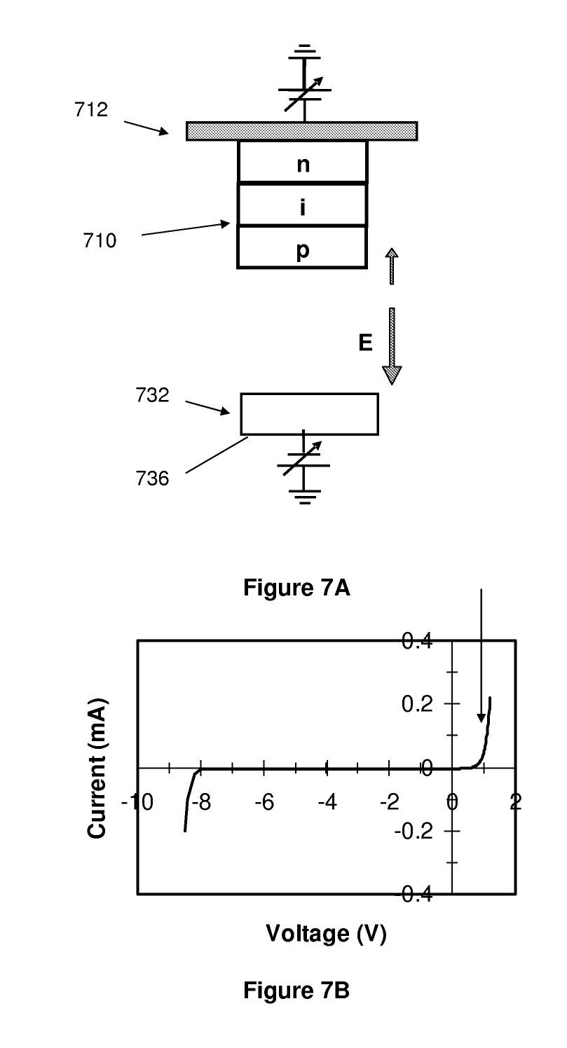

FIG. 7A is a schematic illustration of a solar cell 710 grown on a metal substrate 712. A DC sputtering deposition system 732 (having a cathode 736) is employed to deposit a transparent conductive electrode film onto the solar cell 710. The substrate 712 is subjected to a floating potential or is negatively biased. This condition, in a region near the anode as generally defined by the outer surface of the solar cell 710, results in an electrical field “E” pointing to the substrate 712, as shown in FIG. 7A. This electrical field E leads to a forward bias to the n-i-p junction, as shown by the arrow in the solar cell I-V curve in FIG. 7B. The forward bias prevents damage to the cell created by the positively charged particles.

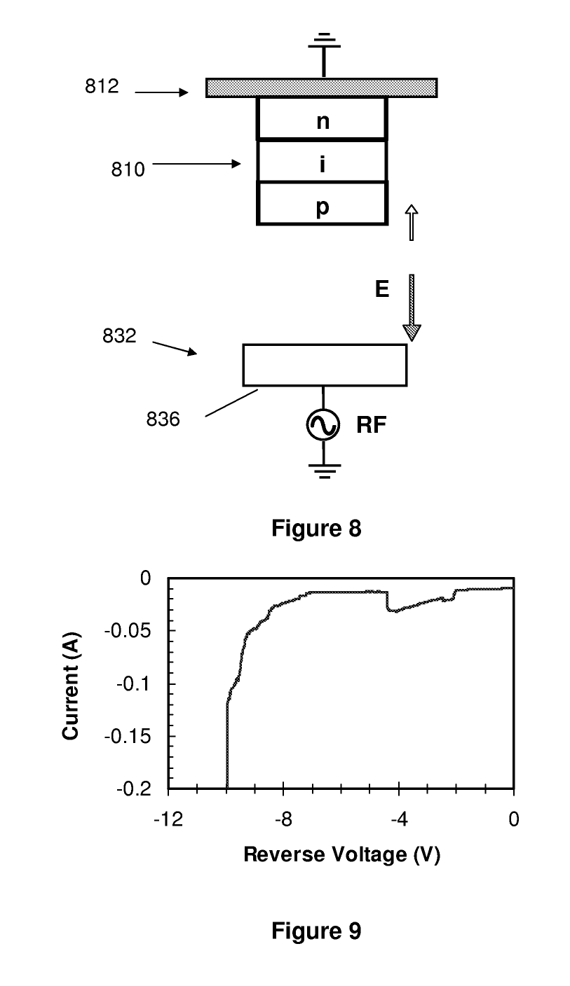

FIG. 8 is a schematic illustration of a solar cell 810 grown on a metal substrate 812. A RF sputtering deposition system 832, having a cathode 836, is employed to deposit a transparent conductive electrode film onto the solar cell 810. The substrate 812 is shown in a grounded condition. The average electrical field in each RF cycle has similar characteristics to DC sputtering with a floating or negatively biased substrate. However, in each RF cycle, there is a phase period, during which the electrical field in the whole region between the cathode (target) and anode (substrate) points to the cathode. During this short period, the characteristics of the electrical field are similar to that of a DC plasma discharge with a grounded and positively biased substrate.

FIG. 9 is a graph showing a reverse I-V curve of a solar cell with a top ITO film deposited by DC sputtering, during which the substrate was set at a floating potential. FIG. 9 confirms that the reverse breakdown voltage is about 8-9 V. This is in agreement with the observation that applying a +20V bias during DC sputtering causes severe damage to the cell, as shown in FIG. 3.

The optimal value and polarity of the applied electrical bias depend on the structure and type of the photovoltaic devices, whether it is n-i-p type or p-i-n type, single junction cell or multi-junction cell. The structure of the solar cell also determines the type of conductive electrode coatings to be applied.

For example, a triple-junction Si-based thin film solar cell can include a nip/nip/nip triple junction cell deposited on a stainless steel substrate such that the “n” layer of the bottom cell is nearest the steel substrate. In this case, a transparent conductive thin film (for example, indium tin oxide, ITO) needs to be deposited on the “p” layer of the top cell to serve as a front electrode.

All of the compositions and methods disclosed and claimed herein can be made and executed without undue experimentation in light of this disclosure. While the compositions and methods of this invention have been described in terms of the foregoing illustrative embodiments, it will be apparent to those skilled in the art that variations, changes, modifications, and alterations may be applied to the compositions and/or methods described herein, without departing from the true concept, spirit, and scope of the invention. More specifically, it will be apparent that certain materials that are chemically and/or electrically related may be substituted for the materials described herein while the same or similar results would be achieved. All such similar substitutes and modifications apparent to those skilled in the art are deemed to be within the spirit, scope, and concept of the invention as defined by the appended claims.

What is claimed is:

1. A method for depositing a thin film material on a solar cell having a doped outer layer, the method comprising:
applying an electrical bias to the solar cell, grounding the solar cell, or setting the solar cell at an electrically floating potential;
generating a plasma of negatively and positively charged particles to produce a sputtering of a target material; and,
depositing the target material as a thin film onto the doped outer layer of the solar cell;
the applied electrical bias, the grounding, or the floating potential reducing the amount of a certain type of charged particles from being deposited on the doped outer layer of the solar cell.

2. The method of claim 1, wherein the solar cell is deposited on a substrate, the method including applying the electrical bias to the substrate, grounding the substrate, or setting the substrate at an electrically floating potential.

3. The method of claim 1, wherein the electrical bias, the grounding, or the floating potential is sufficient to substantially prevent certain type of the charged particles from creating a sufficiently high reverse bias on the solar cell as to damage the solar cell.

4. The method of claim 1, wherein the target material is deposited as a thin film using a sputtering deposition process.

5. The method of claim 1, wherein the thin film includes one or more layers of transparent conductive oxide film(s), one or more layers of metal film(s), or a combination of both.

6. The method of claim 1, wherein the solar cell has a p-type layer as the doped outer layer, the method including applying a negative bias to the solar cell, grounding the solar cell, or setting the solar cell at electrically floating potential.

7. The method of claim 1, wherein the solar cell has an n-type layer as the doped outer layer, the method including applying a positive bias to an opposing inner layer of the solar cell, grounding the solar cell, or setting the solar cell at electrically floating potential.

8. The method of claim 1, wherein the solar cell comprises a single, tandem or triple junction solar cell.

9. A method for reducing damage to a solar cell during a sputtering deposition of a thin film material on a doped outer layer of the solar cell, the method comprising:
applying an electrical bias to the solar cell, grounding the solar cell, or setting the solar cell at electrically floating potential;
generating a plasma of negatively and positively charged particles to produce a sputtering of a target material, and
depositing the target material as a thin film onto the doped outer layer of the solar cell,
wherein the applied electrical bias, the grounding, or the floating potential substantially prevents a certain type of charged particles from being deposited on the outer doped layer of the solar cell to substantially prevent the charged particles from creating a sufficiently high reverse bias on the solar cell as to damage the solar cell.

10. An apparatus for depositing a thin film material on a solar cell having a doped outer layer, comprising:
a device configured for applying an electrical bias to the solar cell, for grounding the solar cell, and/or for setting the solar cell at electrically floating potential; and
a system configured for generating a plasma of negatively and positively charged particles to produce a sputtering of a target material;
the applied electrical bias, the grounding, or the floating potential being sufficient to reduce the amount of a certain type of charged particles from being deposited on the outer doped layer of the solar cell.

11. The apparatus of claim 10, including a sputtering deposition system.

12. An apparatus for reducing damage to a solar cell during a sputtering deposition of a thin film material on an outer layer of the solar cell, comprising:
a system configured for applying an electrical bias to the solar cell, grounding the solar cell, and/or setting the solar cell at electrically floating potential;
a system configured for generating a plasma of negatively and positively charged particles to produce a sputtering of a target material;
the applied electrical bias, the grounding, or the floating potential being sufficient to reduce the amount of a certain type of charged particles from being deposited on the outer doped layer of the solar cell to substantially prevent the charged particles from creating a sufficiently high reverse bias on the solar cell as to damage the solar cell.

13. The apparatus of claim 12, including a sputtering deposition system.

14. An apparatus for sputtering depositing a thin film electrode material on a solar cell having a p-i-n or a n-i-p structure which structure is deposited on a substrate, comprising:
a system configured for applying an electrical bias to the substrate, grounding the substrate, or setting the substrate at electrically floating potential; and
a system configured for generating a plasma of negatively and positively charged particles to produce a sputtering of a target material;
the electrical bias, the grounding, or the floating potential of the substrate reducing the amount of a certain type of charged particles from being deposited on the solar cell.

15. A method for depositing a thin film material on a solar cell having a doped outer layer, comprising:
applying an electrical bias to or grounding of at least one external electrode that is positioned in a spaced relationship to the doped outer layer of the solar cell;
generating a plasma of negatively and positively charged particles to produce a sputtering of a target material, and
depositing the target material onto the doped outer layer of the solar cell;
the electrical bias or the grounding of the external electrode reducing a certain type of the charged particles from being deposited on the doped outer layer of the solar cell.

16. The method of claim 15, wherein the solar cell is deposited on a substrate that may be set at ground, floating, or biased potential.

17. The method of claim 15, wherein the target material is deposited as a thin film using a sputtering deposition process.

18. The method of claim 15, wherein the thin film includes one or more layers of transparent conductive oxide film(s), one or more layers of metal film(s), or a combination of both.

19. The method of claim 15, wherein the solar cell has a p-type layer as the doped outer layer, the method including applying a positive bias to the external electrode or connecting the external electrode at ground potential.

20. The method of claim 15, wherein the solar cell has a n-type layer as the doped outer layer, the method including applying a negative bias to the external electrode or connecting the external electrode at ground potential.

21. The method of claim 15 wherein the solar cell comprises a single, tandem or a triple junction solar cell.

22. A method for reducing damage to a solar cell during a sputtering deposition of a thin film material on a doped outer layer of the solar cell, comprising:
applying an electrical bias to, grounding of, or floating potential to at least one external electrode that is positioned in a spaced relationship to the doped outer layer of the solar cell;
generating a plasma of negatively and positively charged particles to produce a sputtering of a target material, and
depositing the target material onto the doped outer layer of the solar cell,
the applied electrical bias, grounding, or floating potential reducing the amount of a certain type of charged particles from being deposited on the outer doped layer of the solar cell to substantially prevent the charged particles from creating a sufficiently high reverse bias on the solar cell as to damage the solar cell.

23. An apparatus for depositing a thin film material on a solar cell having a doped outer layer, comprising:
at least one external electrode positioned in a spaced relationship to the doped outer layer of the solar cell; and
a system configured for generating a plasma of negatively and positively charged particles to produce a sputtering of a target material;
a device configured to apply electrical bias to or to ground the external electrode to reduce the amount of a certain type of charged particles from being deposited on the outer doped layer of the solar cell.

24. The apparatus of claim 23, including a sputtering deposition system.

25. An apparatus for reducing damage to a solar cell during a sputtering deposition of a thin film material on an outer layer of the solar cell, comprising:
at least one external electrode positioned in a spaced relationship to the doped outer layer of the solar cell; and
a system configured for generating a plasma of negatively and positively charged particles to produce a sputtering of the target material;
a device configured to apply electrical bias to or to ground the external electrode to reduce the amount of a certain type of charged particles from being deposited on the outer doped layer of the solar cell to substantially prevent the charged particles from creating a sufficiently high reverse bias on the solar cell as to damage the solar cell.

26. The apparatus of claim 25, including a sputtering deposition system.

27. A photovoltaic device made using any of the methods of the preceding claims.

28. A photovoltaic device made using any one of the apparatus of the preceding claims.
